(19) United States
(12) Patent Application Publication
(10) Pub. No.: US 2025/0313933 A1
(43) Pub. Date: Oct. 9, 2025

(54) METHOD FOR OPERATING FILM FORMING DEVICE AND FILM FORMING DEVICE

(71) Applicant: Tokyo Electron Limited, Tokyo (JP)

(72) Inventors: Yosuke WATANABE, Yamanashi (JP); Yoshihiro TAKEZAWA, Yamanashi (JP); Tatsuya MIYAHARA, Yamanashi (JP)

(21) Appl. No.: 19/093,922

(22) Filed: Mar. 28, 2025

(30) Foreign Application Priority Data
Apr. 5, 2024 (JP) 2024-061704

(51) Int. Cl. C23C 10/08; B08B 9/08

(52) U.S. Cl. CPC C23C 10/08; B08B 9/08

(57) ABSTRACT

A method for operating a film forming device, the method includes: (a) supplying a silicon-containing gas into a process chamber and coating inside of the process chamber with an amorphous silicon film; (b) supplying a nickel raw material gas into the process chamber after the (a) to form a nickel-containing film; and (c) cleaning the inside of the process chamber by supplying a halogen-containing gas into the process chamber after the (b).

### CROSS-REFERENCE TO RELATED APPLICATIONS

The present application is based on and claims priority to Japanese Patent Application No. 2024-061704 filed on Apr. 5, 2024, the entire contents of which are hereby incorporated by reference.

### BACKGROUND

### 1. Field of the Invention

The present disclosure relates to a method for operating the film forming device and a film forming device.

### 2. Description of the Related Art

There is a known technique to modify an amorphous silicon film into a polycrystalline silicon film by adsorbing nickel particles on a surface of the amorphous silicon film and then performing annealing (see, for example, Japanese Laid-Open Patent Application No. 2011-60908).

### SUMMARY

A method for operating the film forming device according to one aspect of the present disclosure includes (a) supplying a silicon-containing gas into a process chamber and coating the process chamber with an amorphous silicon film, (b) supplying a nickel raw material gas into the process chamber after (a) to form a nickel-containing film, and (c) cleaning inside of the process chamber by supplying a halogen-containing gas into the process chamber after (b).

### BRIEF DESCRIPTION OF THE DRAWINGS

FIG. 1 is a cross-sectional view illustrating a film forming device according to an embodiment;

FIG. 2 is a flowchart illustrating a method for operating the film forming device according to the embodiment; and

FIG. 3 is a chart illustrating examples of nickel concentration and carbon concentration before and after cleaning.

### DETAILED DESCRIPTION OF THE DISCLOSURE

A technique is provided to remove a nickel-containing film deposited in a process chamber.

A non-limiting exemplary embodiment of the present disclosure will be described in the following with reference to the attached drawings. In all of the attached drawings, the same or corresponding members or parts will be assigned the same or corresponding reference numerals, and duplicate descriptions will be omitted.

### Film Forming Device

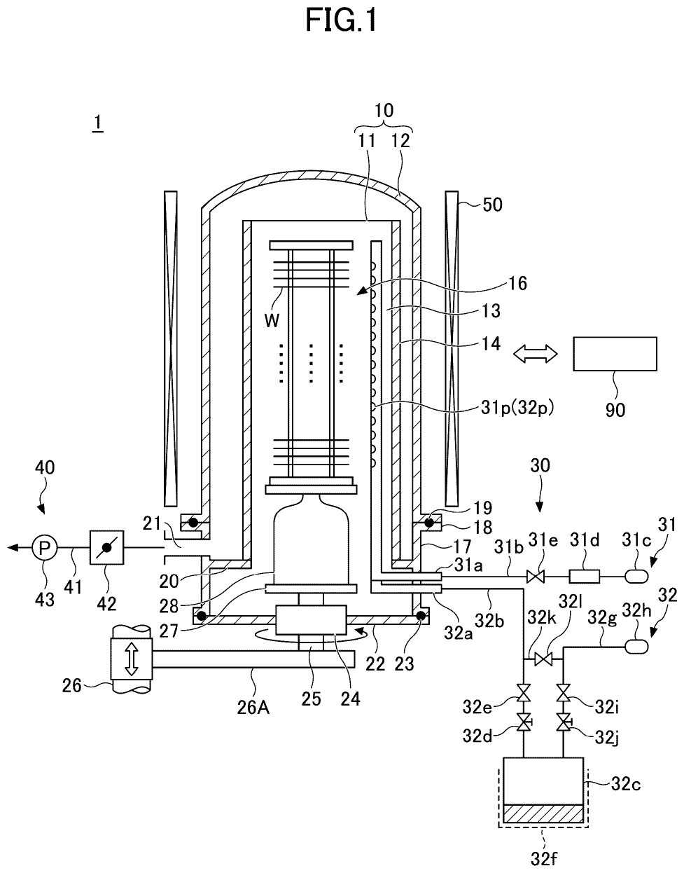

A film forming device 1 according to an embodiment will be described with reference to FIG. 1. FIG. 1 is a cross-sectional view illustrating the film forming device 1 according to an embodiment.

The film forming device 1 includes a process chamber 10, a gas supplier 30, an exhauster 40, a heater 50, and a controller 90.

The process chamber 10 includes a double cylinder structure of an inner cylinder 11 and an outer cylinder 12 with a ceiling mounted concentrically on the outside of the inner cylinder 11. The inner cylinder 11 and the outer cylinder 12 are formed of, for example, quartz. The process chamber 10 is configured to house a boat 16.

A housing portion 13 is formed on one side of the inner cylinder 11 along its longitudinal direction (vertical direction). The housing portion 13 is an area in an inner side of a projecting portion 14 formed by projecting a part of a side wall of the inner cylinder 11 outward. The housing portion 13 houses supply pipes 31a and 32a, which will be described in the following.

The lower end of the process chamber 10 is supported by a cylindrical manifold 17 formed of, for example, a stainless steel. A flange 18 is formed at the upper end of the manifold 17. The flange 18 supports the lower end of the outer cylinder 12. A sealing member 19 such as an O-ring is provided between the flange 18 and the lower end of the outer cylinder 12.

An annular support 20 is provided on an inner wall of an upper part of the manifold 17. The support 20 supports the lower end of the inner cylinder 11. An exhaust port 21 is provided on an upper side wall of the manifold 17 and above the support 20. A lid 22 is hermetically attached to an opening of the lower end of the manifold 17 via a seal 23 such as the O-ring. The lid 22 is formed of, for example, a stainless steel.

A rotary shaft 25 is provided penetrating through the center of the lid 22 through a magnetic fluid seal 24. The lower end of the rotary shaft 25 is rotatably supported by an arm 26A of an elevator 26 including a boat elevator. A rotary plate 27 is provided at the upper end of the rotary shaft 25. The boat 16 is placed on the rotary plate 27 through a thermal cylinder 28 made of quartz.

The boat 16 holds a plurality of substrates W (for example, 25 to 200 substrates) substantially horizontally at intervals in the vertical direction. The substrates W are, for example, semiconductor wafers. The boat 16 rotates integrally with the rotary shaft 25. The boat 16 is vertically moved integrally with the lid 22 by the lifting and lowering of the arm 26A, and is inserted and removed from the process chamber 10.

The gas supplier 30 is configured such that various gases can be introduced into the inner cylinder 11. The gas supplier 30 includes a silicon raw material supplier 31 and a nickel raw material supplier 32.

The silicon raw material supplier 31 includes the supply pipe 31a in the process chamber 10 and a supply path 31b to the outside of the process chamber 10. The supply path 31b is provided with a silicon raw material source 31c, a mass flow controller 31d, and an openable-closable valve 31e in order from upstream to downstream in a gas flow direction. The supply timing of the silicon-containing gas in the silicon raw material source 31c is controlled by the openable-closable valve 31e and adjusted to a predetermined flow rate by the mass flow controller 31d. The silicon-containing gas flows into the supply pipe 31a from the supply path 31b and is discharged into the process chamber 10 from the supply pipe 31a.

The nickel raw material supplier 32 includes the supply pipe 32a in the process chamber 10 and a supply path 32b outside of the process chamber 10. The supply path 32b is provided with a raw material tank 32c, a control valve 32d, and an openable-closable valve 32e in order from upstream to downstream in the gas flow direction. The raw material tank 32c houses a nickel raw material. The nickel raw material is a liquid raw material at room temperature or a solid raw material at room temperature. A heater 32f is provided around the raw material tank 32c. The heater 32f heats the nickel raw material in the raw material tank 32c. As a result, the liquid nickel raw material is vaporized or the solid nickel raw material is sublimated to produce a nickel raw material gas.

The nickel raw material supplier 32 includes a carrier gas pipe 32g inserted from above into the raw material tank 32c. The carrier gas pipe 32g is provided with a carrier gas source 32h, an openable-closable valve 32i, and a control valve 32j in order from upstream to downstream in the gas flow direction. As a result, a carrier gas of the carrier gas source 32h is supplied into the raw material tank 32c while the supply timing is controlled by the openable-closable valve 321 and the flow rate is adjusted to a predetermined flow rate by the control valve 32j. The carrier gas, together with the nickel raw material gas in the raw material tank 32c, flows into the supply pipe 32a from the supply path 32b while the supply timing is controlled by the openable-closable valve 32e and the flow rate is adjusted to a predetermined flow rate by the control valve 32d. The nickel raw material gas and the carrier gas flowing into the supply pipe 32a are discharged from the supply pipe 32a into the process chamber 10.

A bypass path 32k may be provided to connect the upstream of the openable-closable valve 32i in the carrier gas pipe 32g and the downstream of the openable-closable valve 32e in the supply path 32b. A bypass valve 321 may be provided in the bypass path 32k.

The supply pipes 31a and 32a are fixed to the manifold 17. The supply pipes 31a and 32a are formed of, for example, quartz. The supply pipes 31a and 32a extend linearly in the vertical direction in the vicinity of the inner cylinder 11, and extend horizontally by bending in an L-shape inside the manifold 17, thereby penetrating through the manifold 17. The supply pipes 31a and 32a are provided side by side along a circumferential direction of the inner cylinder 11 and are formed at the same height.

In the supply pipes 31a and 32a, a plurality of gas holes 31p and 32p are respectively provided at a portion located inside the inner cylinder 11. The gas holes 31p and 32p are formed at predetermined intervals along an extending direction of the supply pipes 31a and 32a. The gas holes 31p and 32p discharge gas in the horizontal direction. A distance between the gas holes 31p and 32p is set equal to, for example, a distance between the substrates W held by the boat 16. The positions of the gas holes 31p and 32p in a height direction are set at intermediate positions between the substrates W adjacent in the vertical direction. In this case, the gas holes 31p and 32p can efficiently supply gas to facing surfaces of the substrates W adjacent to each other.

The gas supplier 30 may mix a plurality of kinds of gases and discharge the mixed gas from one supply pipe. For example, the supply pipes 31a and 32a may be configured to discharge an inert gas. The supply pipes 31a and 32a may have different shapes and arrangements. The gas supplier 30 may further include a supply pipe for supplying other gases in addition to the silicon-containing gas and the nickel raw material gas.

The exhauster 40 includes an exhaust passage 41, a pressure adjustment valve 42, and a vacuum pump 43. The exhaust passage 41 is connected to the exhaust port 21. The pressure adjustment valve 42 and the vacuum pump 43 are provided in the exhaust passage 41. The vacuum pump 43 is provided downstream of the pressure adjustment valve 42 in the gas flow direction. The gas in the process chamber 10 is discharged to the outside of the process chamber 10 by the vacuum pump 43 while an exhaust flow rate is controlled by the pressure adjustment valve 42.

The heater 50 has a cylindrical shape and is provided around the outer cylinder 12. The heater 50 heats each substrate W in the process chamber 10. The heater 50 includes, for example, a heater.

The controller 90 is an electronic circuit such as a central processing unit (CPU), a field programmable gate array (FPGA), or an application specific integrated circuit (ASIC). The controller 90 executes various control operations described herein by executing an instruction code stored in a memory or by designing a circuit for a special application.

### Method for Operating Film Forming Device

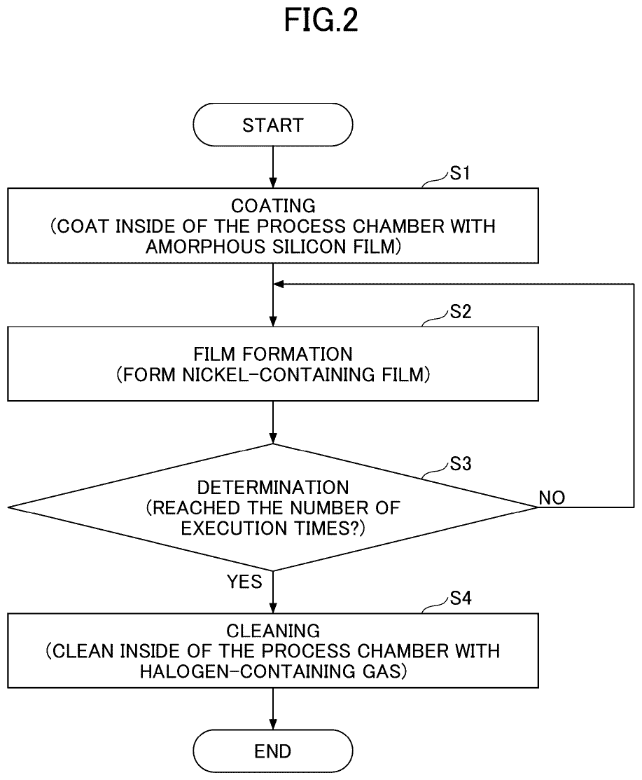

The method for operating the film forming device 1 according to the embodiment will be described with reference to FIG. 2. FIG. 2 is a flowchart illustrating a method for operating the film forming device 1 according to the embodiment. The method for operating the film forming device 1 as illustrated in FIG. 2 is performed under control of the controller 90.

As illustrated in FIG. 2, the method for operating the film forming device 1 includes coating S1, film formation S2, determination S3, and cleaning S4.

The coating S1 includes supplying silicon-containing gas into the process chamber 10 and coating the inside of the process chamber 10 with an amorphous silicon film. The inside of the process chamber 10 includes, for example, an inner wall surface of the process chamber 10 and a surface of the boat 16. The silicon-containing gas is, for example, diisopropylaminosilane (DIPAS), disilane, monosilane, or any combination thereof. The coating S1 is performed in a state where, for example, the boat 16 holding a plurality of dummy substrates Wd is housed in the process chamber 10. The coating S1 may be performed in a state where the boat 16 is not housed in the process chamber 10.

In one embodiment, the elevator 26 carries the boat 16 holding a plurality of dummy substrates Wd into the process chamber 10. Subsequently, the lid 22 hermetically seals the opening at the lower end of the process chamber 10. Subsequently, the exhauster 40 depressurizes the pressure inside of the process chamber 10 to a predetermined pressure, and the heater 50 adjusts the temperature inside the process chamber 10 to a predetermined temperature. Subsequently, the gas supplier 30 supplies silicon-containing gas into the process chamber 10 and coats the inside of the process chamber 10 with an amorphous silicon film, for example, by chemical vapor deposition (CVD). After the inside of the process chamber 10 is coated with an amorphous silicon film of a predetermined thickness, the gas supplier 30 stops supplying silicon-containing gas into the process chamber 10. The predetermined film thickness may be 50 nm or more and 150 nm or less, for example, 100 nm. The gas supplier 30 may stop supplying silicon-containing gas into the process chamber 10 after a predetermined time has elapsed from the start of supplying silicon-containing gas into the process chamber 10. The predetermined time may be the time required for the process chamber 10 to be coated with an amorphous silicon film of a predetermined thickness, and may be determined by a preliminary experiment or the like. Subsequently, the controller 90 boosts the pressure inside the process chamber 10 to an atmospheric pressure and decreases the temperature inside the process chamber 10 to a retrieval temperature. Subsequently, the elevator 26 retrieves the boat 16 holding the plurality of dummy substrates Wd from the process chamber 10.

The film formation S2 is performed after the coating S1. The film formation S2 includes supplying a nickel raw material gas into the process chamber 10 to form a nickel-containing film. The nickel raw material gas can be generated, for example, by vaporizing a liquid nickel raw material. The liquid nickel raw material gas is, for example, (EtCp)₂Ni[Ni(C₂H₅C₅H₄)₂], NiPF₃[Ni(PF₃)₄], CpAllylNi[(C₃H₅) (C₅H₅)Ni], or Ni(CO)₄. The nickel raw material gas can be generated, for example, by sublimating a solid nickel raw material gas. The solid nickel raw material gas is, for example, (MeCp)₂Ni[Ni(CH₃CH₄)₂]. The film formation S2 is performed in a state where, for example, the boat 16 holding a plurality of product substrates Wp is housed in the process chamber 10. In the film formation S2, a nickel-containing film is formed on the plurality of product substrates Wp, and the nickel-containing film is deposited on the amorphous silicon film coating the inside of the process chamber 10.

In one embodiment, the elevator 26 carries the boat 16 holding the plurality of product substrates Wp into the process chamber 10. Subsequently, the lid 22 hermetically closes the opening at the lower end of the process chamber 10 and seals it. Subsequently, the exhauster 40 depressurizes the inside of the process chamber 10 to a predetermined pressure, and the heater 50 adjusts the temperature inside the process chamber 10 to a predetermined temperature. Subsequently, the gas supplier 30 supplies the nickel raw material gas into the process chamber 10, and forms a nickel-containing film on the product substrates Wp by chemical vapor deposition, for example. At this time, the nickel-containing film is also deposited on the amorphous silicon film coating the inside of the process chamber 10. When the nickel-containing film is deposited on the amorphous silicon film, nickel silicide (NiₓSi_{y}, where x>0 and y>0) is formed at an interface between the amorphous silicon film and the nickel-containing film by reacting the amorphous silicon film with the nickel raw material gas. The gas supplier 30 stops supplying the nickel raw material gas into the process chamber 10 after the nickel-containing film having a target film thickness is formed on each of the product substrates Wp. The gas supplier 30 may stop supplying the nickel raw material gas into the process chamber 10 after a predetermined time elapses from the start of supplying the nickel raw material gas into the process chamber 10. The predetermined time may be a time required for forming the nickel-containing film having a target film thickness on the product substrates Wp, and may be determined by a preliminary experiment or the like. Subsequently, the controller 90 boosts the pressure in the process chamber 10 to the atmospheric pressure and reduces the temperature inside the process chamber 10 to the retrieval temperature. Subsequently, the elevator 26 retrieves the boat 16 holding the plurality of product substrates Wp from the process chamber 10.

The determination S3 is performed after the film formation S2. In the determination S3, whether or not the film formation S2 has been performed for a specified number of execution times is determined. When the number of execution times has reached the specified number of execution times (YES in the determination S3), the process proceeds to the cleaning S4. When the number of execution times has not reached the specified number of execution times (NO in the determination S3), the film formation S2 is performed again. That is, the film formation S2 is repeated until the number of execution times reaches the specified number of execution times. When the film formation S2 is repeatedly performed, the thickness of the nickel-containing film deposited in the process chamber 10 increases. When the thickness of the nickel-containing film deposited in the process chamber 10 exceeds a threshold value, the nickel-containing film is peeled off and particles are generated. Therefore, the number of execution times to be specified is set such that the thickness of the nickel-containing film does not exceed the threshold value. The number of execution times to be specified may be once or one or more times.

The cleaning S4 is performed after the determination S3. The cleaning S4 includes cleaning the inside of the process chamber 10 by supplying a halogen-containing gas into the process chamber 10. The halogen-containing gas is, for example, a fluorine (F₂) gas, a chlorine (Cl₂) gas, a chlorine trifluoride (ClF₃) gas, a nitrogen trifluoride (NF₃) gas, a hydrogen fluoride (HF) gas, or a combination thereof.

In one embodiment, the elevator 26 carries the boat 16 without holding the substrates W into the process chamber 10. Subsequently, the lid 22 hermetically seals the opening at the lower end of the process chamber 10. Subsequently, the exhauster 40 depressurizes the inside of the process chamber 10 to a predetermined pressure, and the heater 50 adjusts the temperature inside the process chamber 10 to a predetermined temperature. Subsequently, the gas supplier 30 supplies the halogen-containing gas into the process chamber 10 to clean the inside of the process chamber 10. At this time, since nickel silicide is formed at the interface between the amorphous silicon film and the nickel-containing film, etching proceeds by reacting the nickel silicide with the halogen-containing gas. At this time, the nickel-containing film deposited in the process chamber 10 is removed together with the nickel silicide. Therefore, the nickel-containing film deposited in the process chamber 10 can be readily removed. In contrast to this, when the inside of the process chamber 10 is coated with the nickel-containing film, an etching residue of the nickel-containing film tends to occur. After the nickel-containing film deposited in the process chamber 10 is removed, the gas supplier 30 stops supplying the halogen-containing gas into the process chamber 10. Whether or not the nickel-containing film deposited in the process chamber 10 is removed is determined by an end-point detection monitor such as a plasma optical emission analysis end-point detection monitor. The gas supplier 30 may stop supplying the halogen-containing gas into the process chamber 10 after a predetermined time has elapsed from the start of supplying the halogen-containing gas into the process chamber 10. The predetermined time may be the length of time required for the nickel-containing film deposited in the process chamber 10 to be removed, and may be determined by a preliminary experiment or the like. Subsequently, the controller 90 boosts the pressure in the process chamber 10 to the atmospheric pressure and lowers the temperature inside the process chamber 10 to the retrieval temperature. Subsequently, the elevator 26 retrieves the boat 16 which does not hold the substrates W from the process chamber 10.

Thus, the method for operating the film forming device 1 as illustrated in FIG. 2 is completed. The method for operating the film forming device 1 as illustrated in FIG. 2 may be repeated.

As described above, according to the method for operating the film forming device 1 according to the embodiment, after the inside of the process chamber 10 is coated with an amorphous silicon film, formation of a nickel-containing film over the inside of the process chamber 10 is performed, and then the inside of the process chamber 10 is cleaned by using a halogen-containing gas. In this case, since nickel silicide is formed at the interface between the amorphous silicon film and the nickel-containing film inside the process chamber 10, etching proceeds by reacting the nickel silicide with the halogen-containing gas. At this time, the nickel-containing film deposited inside the process chamber 10 is removed together with the nickel silicide. Therefore, the nickel-containing film deposited in the process chamber 10 can be readily removed.

In the above-described embodiment, the case in which the film formation S2 is performed after the coating S1 has been described, but the present disclosure is not limited thereto. For example, a second coating may be performed between the coating S1 and the film formation S2. The second coating includes supplying a nickel-containing gas into the process chamber 10 in a state where there are no product substrates Wp in the process chamber 10 but dummy substrates Wd are present, and coating the amorphous silicon film deposited inside the process chamber 10 with the nickel-containing film. In this case, since the inside of the process chamber 10 is coated with the nickel-containing film when a first film formation S2 is performed, the environment inside the process chamber 10 when the first film formation S2 is to be performed can be made close to the environment in the process chamber 10 when a second and subsequent film formations S2 are performed. Therefore, variation between the film quality of the nickel-containing film formed on the product substrates Wp in the first film formation S2 and the film quality of the nickel-containing film formed on the product substrates Wp in the second and subsequent film formations S2 can be reduced. In other words, the reproducibility of the processing on the product substrates Wp is enhanced.

### Experimental Results

In the experiment, a nickel-containing film was formed on the amorphous silicon film by using a quartz chip whose surface was coated with an amorphous silicon film instead of using the process chamber 10 whose inner surface was coated with an amorphous silicon film, and then it was confirmed whether or not the nickel-containing film could be removed by using a fluorine gas.

First, a quartz chip whose surface was coated with an amorphous silicon film was prepared. The amorphous silicon film had a thickness of 50 nm. Next, the prepared quartz chip was placed at the bottom of the boat 16, and the boat 16 was carried into the process chamber 10. Next, with the boat 16 housed in the process chamber 10, a nickel raw material gas was supplied into the process chamber 10 to form a nickel-containing film on the surface of the quartz chip. Next, the quartz chip was retrieved from the process chamber 10, and the nickel concentration and the carbon concentration of the retrieved quartz chip were measured by using X-ray photoelectron spectroscopy (XPS). Next, the quartz chip with the nickel-containing film formed was placed at the bottom of the boat 16, and the boat 16 was carried into the process chamber 10. Next, with the boat 16 housed in the process chamber 10, a fluorine gas was supplied into the process chamber 10, and the inside of the process chamber 10 was cleaned. The fluorine gas is an example of the halogen-containing gas. Next, the quartz chip was retrieved from the process chamber 10, and the nickel concentration and the carbon concentration of the carried quartz chip were measured by using X-ray photoelectron spectroscopy.

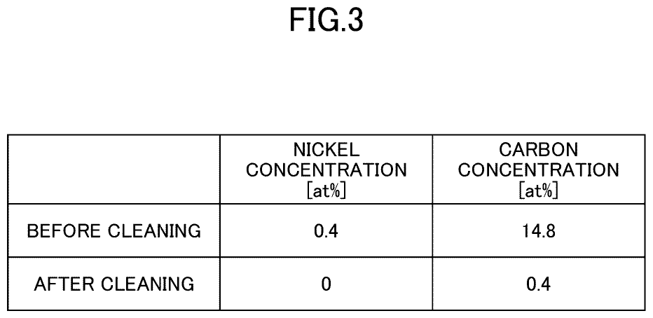

FIG. 3 is a chart illustrating examples of the nickel concentration and the carbon concentration before and after cleaning. As illustrated in FIG. 3, the nickel concentration of the quartz chip before cleaning was 0.4 at % and the carbon concentration was 14.8%. This may be due to the formation of a nickel-containing film on the quartz chip before cleaning. In contrast to this, as illustrated in FIG. 3, the nickel concentration of the quartz chip after cleaning was 0 at % and the carbon concentration was 0.48. This may be due to the removal of the nickel-containing film from the quartz chip by cleaning. From these results, it is considered that the nickel-containing film can be readily removed by using the halogen-containing gas, by coating the inside of the process chamber 10 with an amorphous silicon film before forming the nickel-containing film over the inside of the process chamber 10.

According to the present disclosure, the nickel-containing film deposited in the process chamber can be removed.

The embodiments disclosed herein should be considered to be exemplary in all respects and not restrictive. The above embodiments may be omitted, replaced, or modified in various ways without departing from the scope and purpose of the appended claims.

In the above embodiments, the case where the film forming device is a batch processing device for processing a plurality of substrates at the same time is described, but the present disclosure is not limited thereto. For example, the film forming device may be a single-wafer processing device for processing substrates one by one.

What is claimed is:

1. A method for operating a film forming device, the method comprising:
(a) supplying a silicon-containing gas into a process chamber and coating inside of the process chamber with an amorphous silicon film;
(b) supplying a nickel raw material gas into the process chamber after the (a) to form a nickel-containing film; and
(c) cleaning the inside of the process chamber by supplying a halogen-containing gas into the process chamber after the (b).

2. The method for operating the film forming device according to claim 1, wherein
the (b) includes forming nickel silicide by reacting the amorphous silicon film with the nickel raw material gas.

3. The method for operating the film forming device according to claim 1, wherein
the (b) is performed in a state where there is a product substrate in the process chamber.

4. The method for operating the film forming device according to claim 1, wherein
the (c) is performed in a state where there is no product substrate in the process chamber.

5. The method for operating the film forming device according to claim 1, wherein
the (c) is performed after the (b) is performed for two or more times.

6. The method for operating the film forming device according to claim 1, the method further comprising:
between the (a) and the (b), (d) coating the amorphous silicon film coating the inside of the process chamber with the nickel-containing film, in a state where there is no product substrate in the process chamber.

7. The method for operating the film forming device according to claim 1, wherein
the halogen-containing gas is a fluorine gas.

8. The method for operating the film forming device according to claim 1, wherein
the nickel raw material gas is generated by vaporizing a liquid nickel raw material or sublimating a solid nickel raw material.

9. The method for operating the film forming device according to claim 8, wherein
the nickel raw material is Ni(C₂H₅C₅H₄)₂, Ni(PF₃)₄, (C₃H₅) (C₅H₅)Ni, Ni(CO)₄, or Ni(CH₃C₅H₄)₂.

10. A film forming device, comprising:
a process chamber;
a gas supplier configured to supply a silicon-containing gas, a nickel raw material gas, and a halogen-containing gas into the process chamber; and
a controller, wherein
the controller is configured to perform
(a) supplying the silicon-containing gas into the process chamber and coating inside of the process chamber with an amorphous silicon film;
(b) supplying the nickel raw material gas into the process chamber after the (a) to form a nickel-containing film; and
(c) cleaning the inside of the process chamber by supplying the halogen-containing gas into the process chamber after the (b).
